(19) United States
(12) Patent Application Publication
(10) Pub. No.: US 2019/0229483 A1
(43) Pub. Date: Jul. 25, 2019

(54) ELECTRICAL CONNECTOR RETAINING DEVICE

(71) Applicant: LOTES CO., LTD, Keelung (TW)

(72) Inventor: Tung Ming Ho, Keelung (TW)

(21) Appl. No.: 16/251,256

(22) Filed: Jan. 18, 2019

(30) Foreign Application Priority Data
Jan. 25, 2018 (CN) 201810071744.0

(51) Int. Cl. H01R 43/02; B23K 35/02; H05K 3/34; H05K 3/30; H01R 4/02; H01R 12/57; H01R 12/70

(52) U.S. Cl. CPC H01R 43/0263; B23K 35/0222; H05K 3/3463; H01R 12/7076; H01R 4/02; H01R 12/57; H05K 3/303

(57) ABSTRACT

A retaining device includes a first component and a second component. The first component is fixedly provided with a first solderable metal. The second component is provided with a solderable area. A second solderable metal is fixed to the solderable area. The first component and the second component are retained by soldering the second solderable metal to the first solderable metal. By fixing the first component and the second component through soldering of two solderable metals, the quantity of soldering points can be set according to the actual required retaining force between the first component and the second component, thereby ensuring the stable connection between the first component and the second component. Further, the soldering points occupy a small area and can be provided at multiple positions, thereby greatly enhancing the degree of freedom of positions of the two solders, and providing more options.

### CROSS-REFERENCE TO RELATED PATENT APPLICATION

This non-provisional application claims priority to and the benefit of, pursuant to 35 U.S.C. § 119(a), patent application Serial No. CN201810071744.0 filed in China on Jan. 25, 2018. The disclosure of the above application is incorporated herein in its entirety by reference.

Some references, which may include patents, patent applications and various publications, are cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference were individually incorporated by reference.

### FIELD

The present invention relates to an electrical connector retaining device, and more particularly to an electrical connector retaining device using two solders for soldering.

### BACKGROUND

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

With the development of electronic technology, the fixing between an electrical connector and a circuit board is typically performed by providing a metal component on an insulating body, and inserting it into a fixing hole of the circuit board, such that a stable connection, for example, iron feet, may be formed between the electrical connector and the circuit board.

However, in the fixing manner of providing the metal component, it is generally required to form holes on the insulating body and the circuit board. Due to the existence of tolerances in the manufacturing process, a certain clearance exists between the metal component and the hole, the quantity of the metal components is small, and this fixing manner has a small binding force. When the electrical connector is used for a long time or sustains an impact by an external force, the electrical connector and the circuit board are prone to loosening, thereby affecting the connection between the electrical connector and the circuit board. When a large binding force is required between the insulating body and the circuit board, the volume of the metal component also needs to be correspondingly increased. Further, the metal component is typically located at an end of the insulating body, and no metal components can be added when some positions of the insulating body require a binding force. Thus, the degree of freedom of positions of metal components is low.

Therefore, a heretofore unaddressed need to design an improved retaining device exists in the art to address the aforementioned deficiencies and inadequacies.

### SUMMARY

In view of the above deficiencies, the present invention fixes a first component and a second component in a soldering manner using two solders, with the aim of providing an electrical connector retaining device having a stronger retaining force.

To achieve the foregoing objective, the present invention adopts the following technical solutions.

An electrical connector retaining device includes a first component and a second component; wherein the first component is provided with a colloid, a first solderable metal is adhered to the first component by the colloid, the second component is provided with a solderable area, a second solderable metal fixes the solderable area to the first solderable metal, the first component and the second component are retained by soldering the second solderable metal to the first solderable metal, and the first component and the second component are not electrically connected to each other through the first solderable metal and the second solderable metal.

In certain embodiments, a melting point of the first solderable metal is higher than a soldering temperature at which the second solderable metal is soldered to the first solderable metal, and a melting point of the second solderable metal is lower than the soldering temperature at which the second solderable metal is soldered to the first solderable metal.

In certain embodiments, a melting point of the colloid is higher than a soldering temperature at which the second solderable metal is soldered to the first solderable metal.

In certain embodiments, a melting point of the colloid is higher than a melting point of the first solderable metal.

In certain embodiments, a shape of the colloid and a shape of the first solderable metal remain intact before and after soldering the second solderable metal to the first solderable metal.

In certain embodiments, the first component is a circuit board, and the circuit board is provided with an electrical connector.

In certain embodiments, the electrical connector has a metal member fixed to the circuit board.

In certain embodiments, the first component is an electrical connector.

In certain embodiments, the second component is a circuit board.

In certain embodiments, the colloid is a thermosetting colloid.

In certain embodiments, the first solderable metal is a tin alloy.

In certain embodiments, a shape of the first solderable metal is a sphere.

In certain embodiments, the solderable area is a copper brazing pad.

In certain embodiments, the second component is provided with a plurality of solderable areas, a plurality of second solderable metals are fixed in the solderable areas respectively, and each of the second solderable metals corresponds to only one of the solderable areas.

In certain embodiments, the solderable area is provided with a plurality of second solderable metals.

In certain embodiments, the second component has only one solderable area, and the solderable area is provided with the second solderable metals.

Compared with the related art, certain embodiments of the present invention have the beneficial effects:

By fixing the first component and the second component through soldering of two solderable metals, the quantity of soldering points can be set according to the actual required retaining force between the first component and the second component, thereby ensuring the stable connection between the first component and the second component. Further, the soldering points occupy a small area and can be provided at multiple positions, thereby greatly enhancing the degree of freedom of positions of the two solders, and providing more options.

A retaining device includes: a first component, being a part made by a metal plate and soldered with a first solderable metal; and a second component, being a circuit board, wherein the second component is provided with a solderable area, the solderable area is fixed with a second solderable metal, and the second solderable metal is a tin alloy; wherein the second solderable metal is in contact with the first solderable metal, and the first component and the second component are retained by soldering the second solderable metal to the first solderable metal.

In certain embodiments, a melting point of the first solderable metal is higher than a soldering temperature at which the second solderable metal is soldered to the first solderable metal, and a melting point of the second solderable metal is lower than the soldering temperature at which the second solderable metal is soldered to the first solderable metal.

In certain embodiments, a shape of the first solderable metal remains intact before and after soldering and retaining the first solderable metal and the second solderable metal.

In certain embodiments, the first solderable metal is a tin alloy having a composition different from the second solderable metal.

Compared with the related art, certain embodiments of the present invention have the beneficial effects:

By soldering two solderable metals with each other to fix the first component and the second component, the quantity of soldering points can be set according to the actual required retaining force between the first component and the second component, thereby ensuring the stable mechanical connection between the first component and the second component. Further, the soldering points occupy a small area and can be provided at multiple positions, thereby greatly enhancing the degree of freedom of positions of the two solders, and providing more options. Meanwhile, the first component and the second component may be electrically connected.

These and other aspects of the present invention will become apparent from the following description of the preferred embodiment taken in conjunction with the following drawings, although variations and modifications therein may be effected without departing from the spirit and scope of the novel concepts of the disclosure.

### BRIEF DESCRIPTION OF THE DRAWINGS

The accompanying drawings illustrate one or more embodiments of the disclosure and together with the written description, serve to explain the principles of the disclosure. Wherever possible, the same reference numbers are used throughout the drawings to refer to the same or like elements of an embodiment, and wherein:

FIG. 1 is a perspective exploded view of an electrical connector retaining device according to a first embodiment of the present invention.

FIG. 2 is a front exploded sectional view of the electrical connector retaining device according to the first embodiment of the present invention.

FIG. 3 is an exploded sectional view of the electrical connector retaining device according to the first embodiment of the present invention before soldering.

FIG. 4 is an exploded sectional view of a soldering process of the electrical connector retaining device according to the first embodiment of the present invention.

FIG. 5 is a front assembled sectional view of the electrical connector retaining device according to the first embodiment of the present invention after soldering.

FIG. 6 is a front view of the electrical connector retaining device according to the first embodiment of the present invention, where the first component is a circuit board.

FIG. 7 is a front view of the electrical connector retaining device according to the first embodiment of the present invention, where the first component is an electrical connector.

FIG. 8 is a perspective exploded view of an electrical connector retaining device according to a second embodiment of the present invention.

FIG. 9 is a perspective exploded view of an electrical connector retaining device according to a third embodiment of the present invention.

FIG. 10 is a front view of an electrical connector retaining device according to a fourth embodiment of the present invention, where the first component is a part made by a metal plate.

### DETAILED DESCRIPTION

The present invention is more particularly described in the following examples that are intended as illustrative only since numerous modifications and variations therein will be apparent to those skilled in the art. Various embodiments of the invention are now described in detail. Referring to the drawings, like numbers indicate like components throughout the views. As used in the description herein and throughout the claims that follow, the meaning of “a”, “an”, and “the” includes plural reference unless the context clearly dictates otherwise. Also, as used in the description herein and throughout the claims that follow, the meaning of “in” includes “in” and “on” unless the context clearly dictates otherwise. Moreover, titles or subtitles may be used in the specification for the convenience of a reader, which shall have no influence on the scope of the present invention.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

As used herein, “around”, “about” or “approximately” shall generally mean within 20 percent, preferably within 10 percent, and more preferably within 5 percent of a given value or range. Numerical quantities given herein are approximate, meaning that the term “around”, “about” or “approximately” can be inferred if not expressly stated.

As used herein, the terms “comprising”, “including”, “carrying”, “having”, “containing”, “involving”, and the like are to be understood to be open-ended, i.e., to mean including but not limited to.

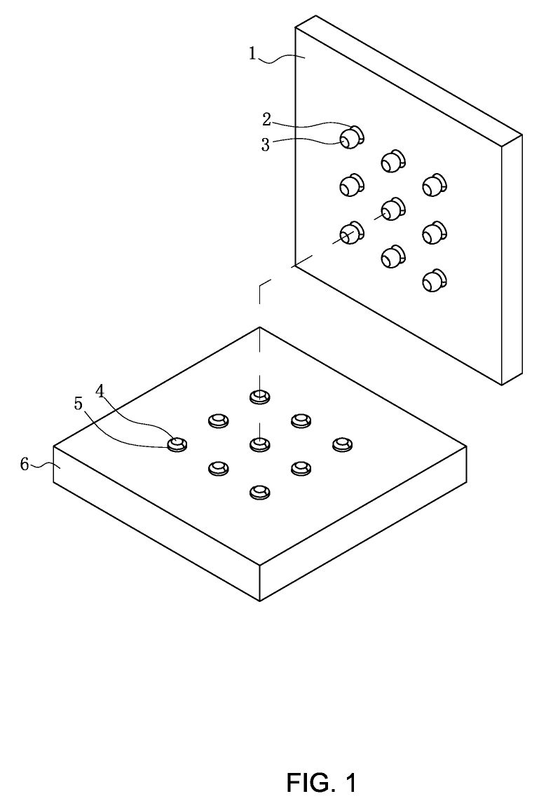

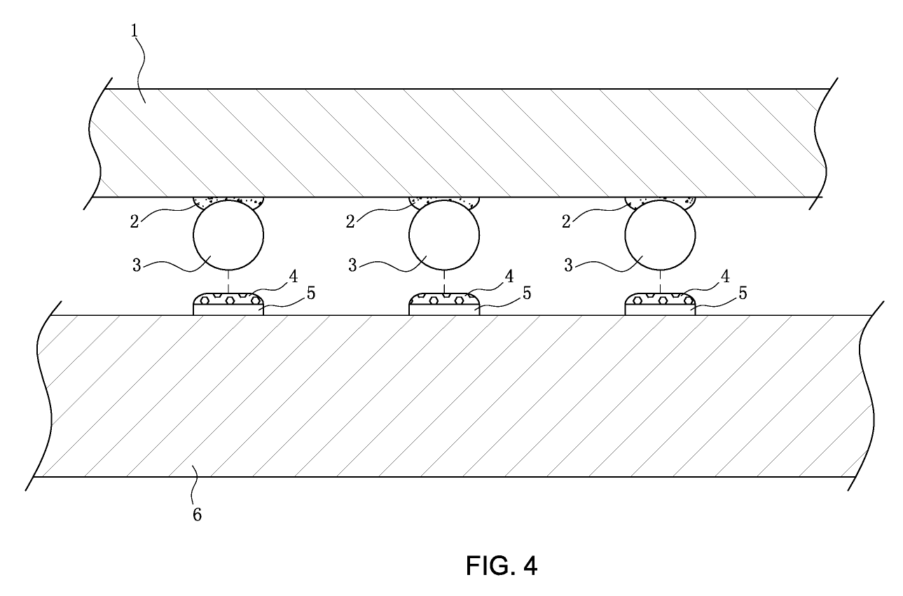

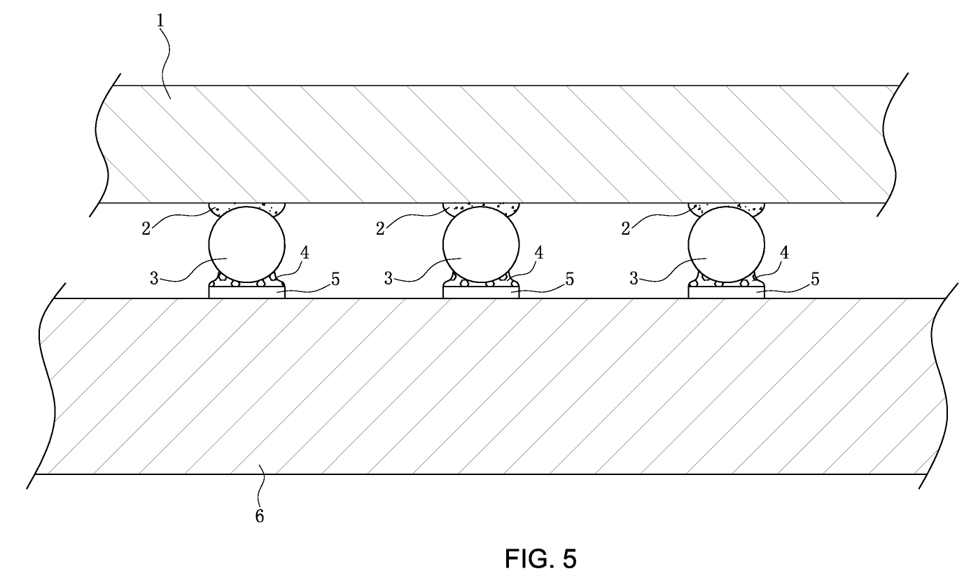

The description will be made as to the embodiments of the present invention in conjunction with the accompanying drawings in FIGS. 1-9. In accordance with the purposes of this invention, as embodied and broadly described herein, this invention, in one aspect, relates to an electrical connector retaining device.

As shown in FIG. 1, an electrical connector retaining device according to a first embodiment of the present invention includes a first component 1 and a second component 6. The first component 1 and the second component 6 are soldered and connected to each other by multiple first solderable metals 3 and multiple second solderable metals 4.

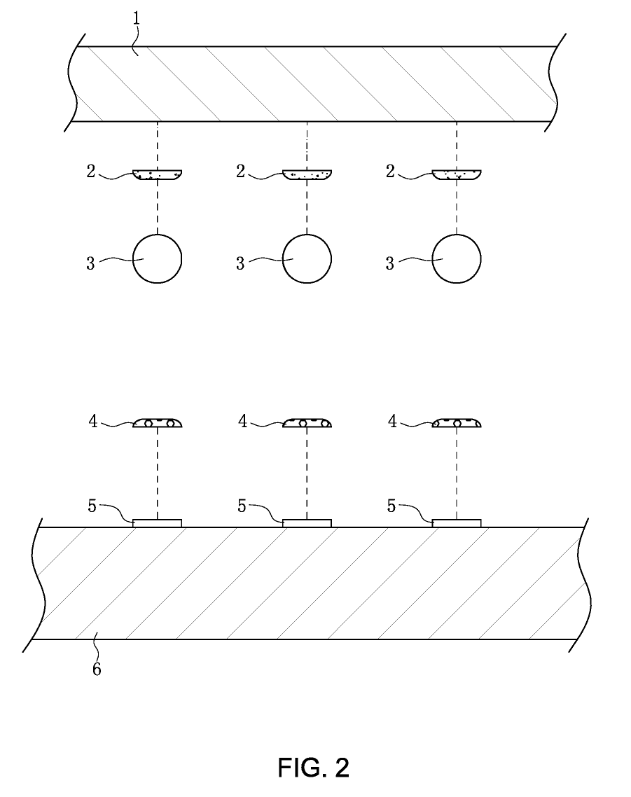

As shown in FIG. 2, from top to bottom, the electrical connector retaining device according to the first embodiment of the present invention is composed of the first component 1, multiple colloids 2, the first solderable metals 3, the second solderable metals 4, multiple solderable areas 5 and the second component 6. The first component 1 and the first solderable metals 3 are adhered together by the colloids 2. Each of the solderable areas 5 is a copper brazing pad. The second solderable metals 4 are provided on the solderable areas 5. Each of the second solderable metals 4 corresponds to only one of the solderable areas 5. Further, the first solderable metals 3 and the second solderable metals 4 are soldered to each other, so as to implement the connection between the first component 1 and the second component 6. Each colloid 2 is a viscoloid, which is made of a thermosetting epoxy resin material and is gradually cured under heating to achieve a fixing effect, and has a melting point of 300° C. Each first solderable metal 3 is a tin-silver-copper alloy and is in a spherical shape. A composition standard of the first solderable metals 3 is: 96.5% of tin, 3% of silver and 0.5% of copper. The melting point is of the first solderable metals 3 217° C. Each second solderable metal 4 is a tin-bismuth alloy. A first composition standard of the second solderable metals 4 is: 64% of tin, 35% of bismuth and 1% of silver, and the melting point of the second solderable metals 4 is 178° C. A second composition standard of the second solderable metals 4 is: 42% of tin and 58% of bismuth, and the melting point of the second solderable metals 4 is 138° C. The second component 6 is typically a circuit board, and the solderable areas 5 are provided on the circuit board.

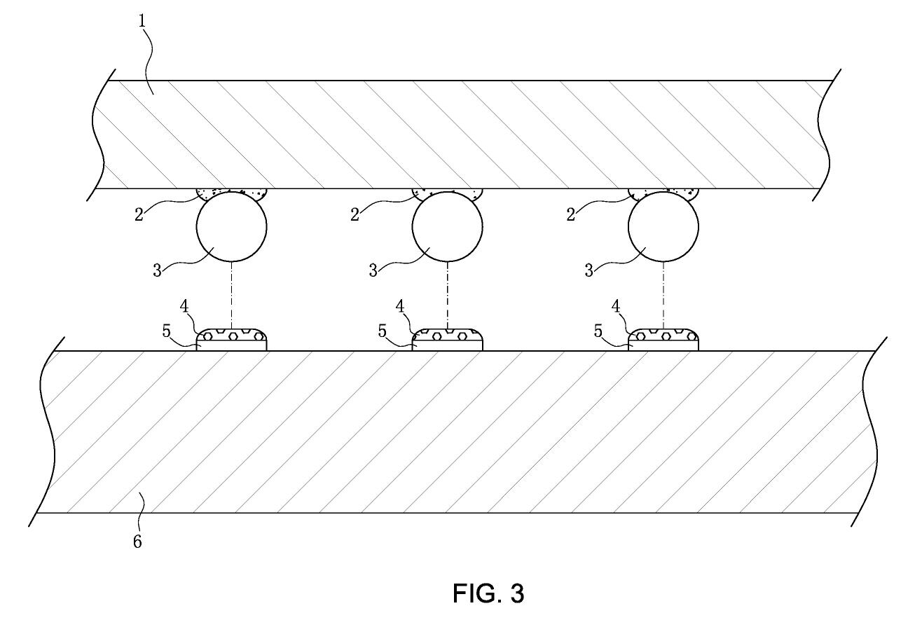

As shown in FIG. 3 to FIG. 5, implementation of the electrical connector retaining device includes three steps, including the combination of the first component 1 and the first solderable metals 3, the combination of the second solderable metals 4 and the second component 6, and the combination of the first component 1 and the second component 6. In the first step, firstly, the first component 1 is uniformly brushed with the colloids 2, and then each first solderable metal 3 is placed on a corresponding position brushed with the colloids 2 on the first component 1, so as to implement pre-fixing between the first component 1 and the first solderable metals 3. In the second step, the second solderable metals 4 are provided on the solderable areas 5 on the second component 6 in advance. In the third step, the first component 1, combined with the first solderable metals 3, and the second component 6, where the second solderable metals 4 are provided on the solderable areas 5 in advance, are placed in a reflow oven to perform soldering at a specific soldering temperature. The specific soldering temperature is lower than the melting point of the colloids 2 and the first solderable metals 3, and higher than the melting point of the second solderable metals 4. During soldering at the specific soldering temperature, the colloids 2, which are thermosetting epoxy resins, can be gradually cured so as to implement a stable connection between the first component 1 and the first solderable metals 3. Further, in the whole soldering process, the melting point of the colloids 2 and the melting point of the first solderable metals 3 are respectively higher than the specific soldering temperature, such that the colloids 2 and the first solderable metals 3 do not melt. Thus, the shapes of the colloids 2 and the first solderable metals 3 remain intact before and after soldering in the reflow oven. The melting point of the second solderable metals 4 is lower than the specific soldering temperature, and therefore, the second solderable metals 4 are in a molten state, thereby implementing the soldering between the first solderable metals 3 and the second solderable metals 4, and further implementing the retaining and connection between the first component 1 and the second component 6. Since the colloids 2 are the thermosetting epoxy resins and are provided between the first component 1 and the first solderable metals 3, the first component 1 and the second component 6 are not electrically connected.

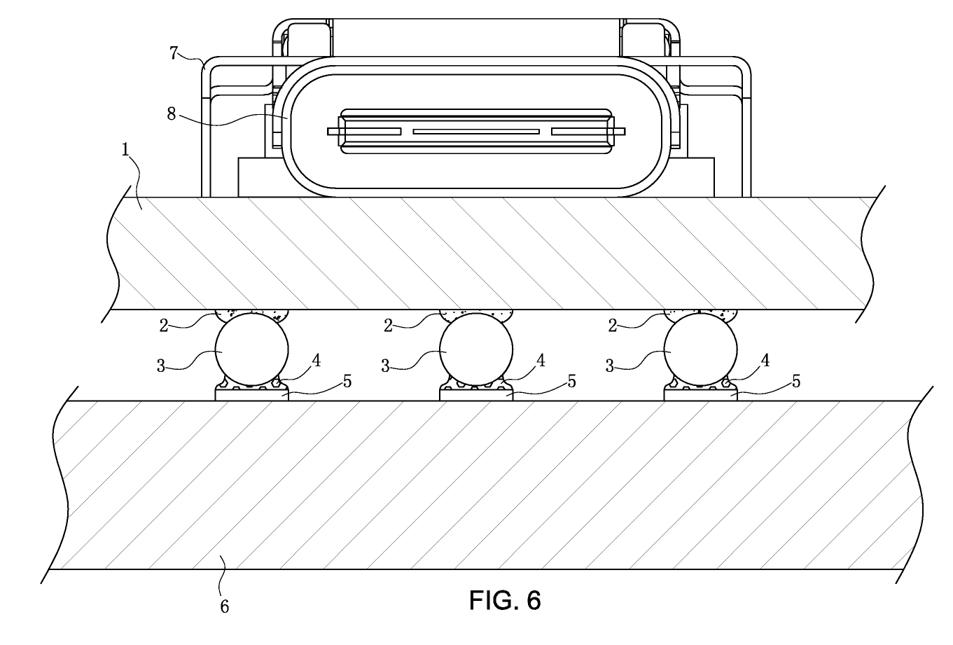

As shown in FIG. 6, the first component 1 may be a circuit board. The first component 1 is provided with an electrical connector 8, and the electrical connector 8 has a metal member 7 fixed to the first component 1. The first component 1 implements the retaining between the electrical connector 8 and the second component 6 by soldering the first solderable metals 3 and the second solderable metals 4 with each other, and reference may be made to the above implementation manner.

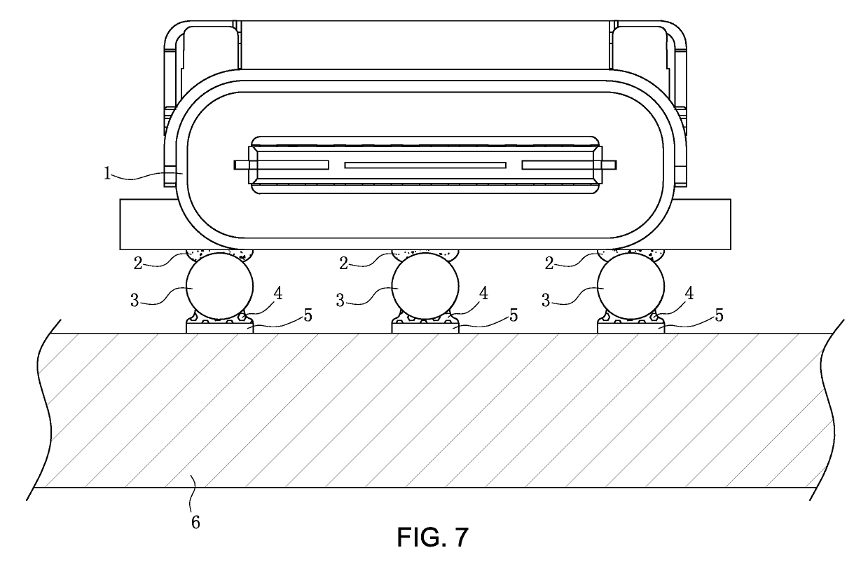

As shown in FIG. 7, the first component 1 may be an electrical connector. The first component 1 implements the retaining between the first component 1 and the second component 6 by soldering the first solderable metals 3 and the second solderable metals 4 with each other, and reference may be made to the above implementation manner. The first component 1 of the present invention is not limited to the electrical connector described herein, and may be other possible components.

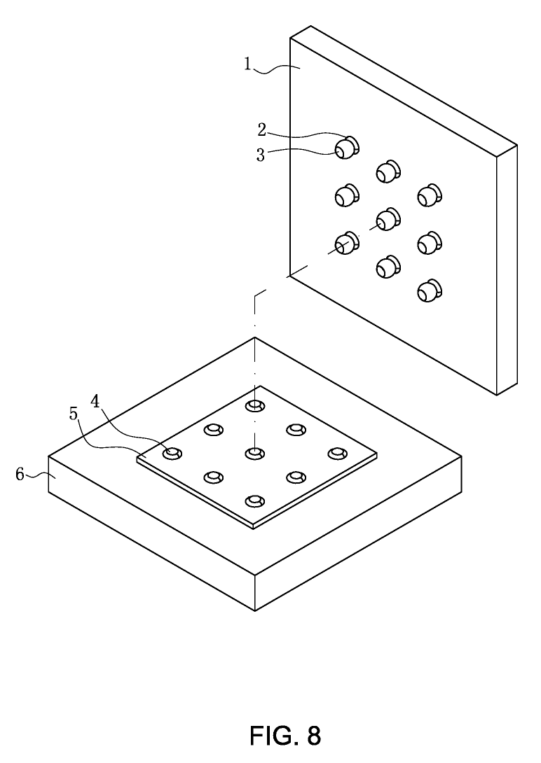

FIG. 8 shows an electrical connector retaining device according to second embodiment of the present invention. The difference between the second embodiment and the first embodiment exists in that: the second component 6 has only one solderable area 5, and the solderable area 5 is provided with multiple second solderable metals 4. For the implementation manner of retaining between the first component 1 and the second component 6, reference may be made to the first embodiment.

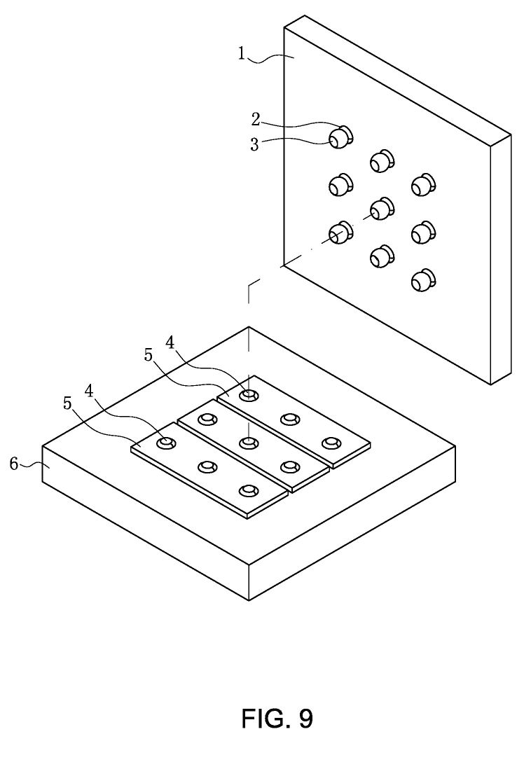

FIG. 9 shows an electrical connector retaining device according to a third embodiment of the present invention. The difference between the third embodiment and the first embodiment exists in that: the second component 6 is provided with multiple solderable areas 5, and each of the solderable areas 5 is provided with multiple second solderable metals 4. For the implementation manner of retaining between the first component 1 and the second component 6, reference may be made to the first embodiment.

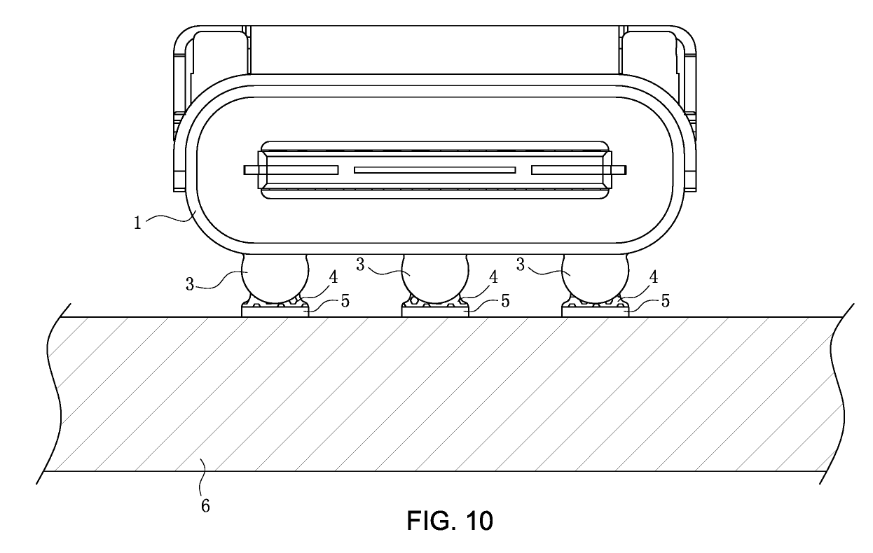

FIG. 10 shows an electrical connector retaining device according to a fourth embodiment of the present invention. The difference between the fourth embodiment and the first embodiment exists in that: the first component 1 is a part made by a metal plate, the first component 1 is used as a metal shell of an electrical connector, and the first component 1 is not provided with the colloids for fixing the first solderable metals 3 to the first component 1. Before soldering and retaining the first component 1 and the second component 6 with each other, the first solderable metals 3 may be directly soldered to the first component 1 in advance, or the first solderable metals 3 may be fixed to the first component 1 by other solders, so as to implement the fixing between the first component 1 and the first solderable metals 3. The second component 6 is a circuit board. The second component 6 is provided with multiple solderable areas 5, and each of the solderable areas 5 is fixed with a second solderable metal 4. Each of the second solderable metals 4 is in contact with one of the first solderable metals 3. The first component 1 and the second component 6 are retained by soldering the second solderable metals 4 to the first solderable metals 3. Each first solderable metal 3 and each second solderable metal 4 are both tin alloys, but have different compositions thereof. The compositions of the first solderable metals 3 and the second solderable metals 4 may be respectively the same as those in the first embodiment, or may be different from those in the first embodiment. The melting point of the first solderable metals 3 is higher than the soldering temperature at which the second solderable metals 4 are soldered to the first solderable metals 3, and the melting point of the second solderable metal 4 is lower than the soldering temperature at which the second solderable metals 4 are soldered to the first solderable metals 3. Therefore, before and after soldering and retaining the first solderable metals 3 and the second solderable metals 4, the shape of each first solderable metal 3 remains intact. In this embodiment, the first component 1 and the second component 2 may be electrically connected.

To sum up, the electrical connector retaining device according to certain embodiments of the present invention adopts a soldering manner using two solders to fix fixes two components, which has the following beneficial effects comparing to the traditional retaining manner of the iron feet:

(1) The traditional iron feet have a large volume and a small quantity, and it is required to form holes in the first component 1 and the second component 6, such that there is a certain clearance between each iron foot and the corresponding hole. The number of process steps is large, and the retaining force of the iron feet to the first component 1 and the second component 6 is limited. When the device is used for a long time or sustain an impact by an external force, the first component 1 and the second component 6 are prone to loosening. In the present invention, two solders are used for retaining the two components, and a plurality of soldering points can be set according to the demand to enhance the retaining force between the first component 1 and the second component 6.

(2) Conventionally, the iron feet setting positions are typically located at the end of the first component 1. When it is necessary to increase the retaining force between the first component 1 and the second component 6, the volume of each iron foot is correspondingly increased to maintain the retaining force therebetween. The iron feet are typically provided at the end of the first component 1, so the degree of freedom of positions of the conventional iron feet is lower. When certain positions of the first component 1 need the retaining force, it may be not possible to provide the iron feet. In the present invention, two solders are used for retaining the two components, and the solders may be provided in many positions due to the small volume, and therefore, the degree of freedom is higher.

(3) The melting point of the colloids 2 in the present invention is much higher than the melting point of the first solderable metals 3. When the first component 1 and the second component 6 are separated, the first component 1 is still retained to the first solderable metals 3 by the action of the colloids 2. To recover the first solderable metals 3 at this time, the first solderable metals 3 may be melted by high temperature while the colloids 2 do not melt, and therefore, the purity of the melted first solderable metals 3 is not affected, and the recovery rate is higher.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments were chosen and described in order to explain the principles of the invention and their practical application so as to activate others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. An electrical connector retaining device, comprising:
a first component and a second component;
wherein the first component is provided with a colloid, a first solderable metal is adhered to the first component by the colloid, the second component is provided with a solderable area, a second solderable metal fixes the solderable area to the first solderable metal, the first component and the second component are retained by soldering the second solderable metal to the first solderable metal, and the first component and the second component are not electrically connected to each other through the first solderable metal and the second solderable metal.

2. The electrical connector retaining device according to claim 1, wherein a melting point of the first solderable metal is higher than a soldering temperature at which the second solderable metal is soldered to the first solderable metal, and a melting point of the second solderable metal is lower than the soldering temperature at which the second solderable metal is soldered to the first solderable metal.

3. The electrical connector retaining device according to claim 1, wherein a melting point of the colloid is higher than a soldering temperature at which the second solderable metal is soldered to the first solderable metal.

4. The electrical connector retaining device according to claim 1, wherein a melting point of the colloid is higher than a melting point of the first solderable metal.

5. The electrical connector retaining device according to claim 1, wherein a shape of the colloid and a shape of the first solderable metal remain intact before and after soldering the second solderable metal to the first solderable metal.

6. The electrical connector retaining device according to claim 1, wherein the first component is a circuit board, and the circuit board is provided with an electrical connector.

7. The electrical connector retaining device according to claim 6, wherein the electrical connector has a metal member fixed to the circuit board.

8. The electrical connector retaining device according to claim 1, wherein the first component is an electrical connector.

9. The electrical connector retaining device according to claim 1, wherein the second component is a circuit board.

10. The electrical connector retaining device according to claim 1, wherein the colloid is a thermosetting colloid.

11. The electrical connector retaining device according to claim 1, wherein the first solderable metal is a tin alloy.

12. The electrical connector retaining device according to claim 1, wherein a shape of the first solderable metal is a sphere.

13. The electrical connector retaining device according to claim 1, wherein the solderable area is a copper brazing pad.

14. The electrical connector retaining device according to claim 1, wherein the second component is provided with a plurality of solderable areas, a plurality of second solderable metals are fixed in the solderable areas respectively, and each of the second solderable metals corresponds to only one of the solderable areas.

15. The electrical connector retaining device according to claim 1, wherein the solderable area is provided with a plurality of second solderable metals.

16. The electrical connector retaining device according to claim 15, wherein the second component has only one solderable area, and the solderable area is provided with the second solderable metals.

17. A retaining device, comprising:
a first component, being a part made by a metal plate and soldered with a first solderable metal; and
a second component, being a circuit board, wherein the second component is provided with a solderable area, the solderable area is fixed with a second solderable metal, and the second solderable metal is a tin alloy;
wherein the second solderable metal is in contact with the first solderable metal, and the first component and the second component are retained by soldering the second solderable metal to the first solderable metal.

18. The retaining device according to claim 17, wherein a melting point of the first solderable metal is higher than a soldering temperature at which the second solderable metal is soldered to the first solderable metal, and a melting point of the second solderable metal is lower than the soldering temperature at which the second solderable metal is soldered to the first solderable metal.

19. The retaining device according to claim 17, wherein a shape of the first solderable metal remains intact before and after soldering and retaining the first solderable metal and the second solderable metal.

20. The retaining device according to claim 17, wherein the first solderable metal is a tin alloy having a composition different from the second solderable metal.
